(19) United States
(12) Patent Application Publication
(10) Pub. No.: US 2026/0160835 A1
(43) Pub. Date: Jun. 11, 2026

(54) SENSOR DEVICES AND ASSOCIATED PRODUCTION METHODS

(71) Applicant: Infineon Technologies AG, Neubiberg (DE)

(72) Inventors: Rainer SCHALLER, Aichen (DE); Edward FÜRGUT, Dasing (DE); Hermann GRUBER, Wörth a. D. (DE)

(21) Appl. No.: 19/413,768

(22) Filed: Dec. 9, 2025

(30) Foreign Application Priority Data
Dec. 11, 2024 (DE) 102024137122.6

(51) Int. Cl. G01R 33/06; G01R 3/00; G01R 33/00

(52) U.S. Cl. CPC G01R 33/06; G01R 3/00; G01R 33/0094

(57) ABSTRACT

A sensor device includes a sensor chip having at least one sensor element which is arranged on a front side of the sensor chip and is configured to capture a physical variable, an electrically insulating material which is arranged on the front side of the sensor chip and surrounds the at least one sensor element, and an electrically insulating layer arranged over a rear side of the sensor chip opposite the front side.

### CROSS-REFERENCE TO RELATED APPLICATION

This application claims priority to Germany Patent Application No. 102024137122.6 filed on Dec. 11, 2024, the content of which is incorporated by reference herein in its entirety.

### TECHNICAL FIELD

The present disclosure relates to sensor devices and methods for producing such sensor devices.

### BACKGROUND

In sensor devices, high electrical voltage differences between individual device components may occur. By way of example, increased electrical potential differences may arise in a current sensor between a busbar and a sensor chip arranged thereabove. Depending on material properties and a relative arrangement of the device components, the increased voltage differences may lead to enormously high electric field strengths in specific spatial regions of the respective sensor device. The elements arranged there may be subject to high wear as a result of the high electric field strengths, which in the worst case may lead to failure of the device. Conventional solutions for isolating components at different electrical potentials are usually costly and complex.

It may be of interest to manufacturers and developers of sensor devices to solve the above-mentioned technical problems in order to both extend the service life of the devices and ensure their continuously safe operation. At the same time, it may be desirable to provide cost-effective and efficient methods for producing the improved sensor devices.

### SUMMARY

Various aspects relate to a sensor device. The sensor device includes a sensor chip having at least one sensor element which is arranged on a front side of the sensor chip and is configured to capture a physical variable. The sensor device further includes an electrically insulating material which is arranged on the front side of the sensor chip and surrounds the at least one sensor element. The sensor device further includes an electrically insulating layer arranged over a rear side of the sensor chip opposite the front side.

Various aspects relate to a method for producing a sensor device. The method includes producing a multiplicity of sensor elements on a front side of a semiconductor wafer, wherein the sensor elements are configured to capture a physical variable. The method further includes forming an electrically insulating material on the front side of the semiconductor wafer, wherein the electrically insulating material surrounds at least one sensor element of the multiplicity of sensor elements. The method further includes forming an electrically insulating layer on a rear side of the semiconductor wafer opposite the front side. The method further includes singulating the semiconductor wafer into a multiplicity of sensor devices.

A person skilled in the art will discern further features and advantages of the implementation upon reading the following detailed description and examining the attached drawings.

### BRIEF DESCRIPTION OF THE DRAWINGS

The present disclosure is shown in an example and non-limiting manner in the illustrations of the attached drawings, in which identical reference signs refer to similar or identical elements. The elements in the drawings are not necessarily depicted to scale in relation to each other. The features of the various examples shown can be combined, provided that they are not mutually exclusive.

FIG. 1 schematically shows a perspective view of a sensor device 100.

FIGS. 2A and 2B schematically show a cross-sectional side view and a plan view of a sensor device 200 according to the disclosure.

FIG. 3 schematically shows a cross-sectional side view of a sensor device 300 according to the disclosure.

FIG. 4 schematically shows a cross-sectional side view of a sensor device 400 according to the disclosure.

FIG. 5 schematically shows a cross-sectional side view of a sensor device 500 according to the disclosure.

FIG. 6 schematically shows a cross-sectional side view of a sensor device 600 according to the disclosure.

FIG. 7 shows a flowchart of a method for producing a sensor device according to the disclosure.

### DETAILED DESCRIPTION

The method of operation of a sensor device 100 is first described qualitatively and by way of example in FIG. 1. The sensor device 100 can have an electrically conductive chip carrier 2 and a sensor chip 4 arranged thereabove. The sensor chip 4 can be for example a magnetic field sensor chip having at least one sensor element 6. In the specific example in FIG. 1, the sensor chip 4 may be a differential magnetic field sensor chip having two Hall sensor elements 6A, 6B.

The electrically conductive carrier 2 can perform the function of a busbar and can be configured to carry an electrical measurement current 8. In the example shown, the chip carrier 2 or the busbar formed by it can have two lateral indentations, such that the measurement current 8 can take a substantially s-shaped course around the two sensor elements 6A, 6B. A magnetic field can be generated at the locations of the sensor elements 6A, 6B by the measurement current 8. The sensor chip 4 can be configured to capture the induced magnetic field at the positions of the sensor elements 6A, 6B. The intensity of the measurement current 8 can be determined based on the captured magnetic field (or based on an associated differential measurement signal). For this reason, the sensor chip 4 or the sensor device 100 can also be referred to as a current sensor.

The sensor device 200 in FIGS. 2A and 2B can have one or more features of the sensor device 100 in FIG. 1. The sensor device 200 may have a sensor chip 4 having at least one sensor element 6 which may be arranged on a front side 10 of the sensor chip 4 and may be configured to capture a physical variable. The sensor device 200 may further have an electrically insulating material 12 which is arranged on the front side 10 of the sensor chip 4 and surrounds the at least one sensor element 6. The sensor device 100 may also contain an electrically insulating layer 16 arranged over a rear side 14 of the sensor chip 4, the rear side 14 being arranged opposite the front side 10. In the example shown, the sensor device 200 may have an electrically conductive chip carrier 2, wherein the sensor chip 4 may be arranged above a portion 18 of the chip carrier 2. In some examples, the chip carrier 2 may be considered to be part of the sensor device 200, while in other examples it need not necessarily constitute a part of the sensor device 200.

For example, the electrically conductive chip carrier 2 may be a leadframe. The leadframe 2 can be produced from a metal and/or a metal alloy, in particular from at least one of copper, copper alloys, nickel, iron-nickel, aluminium, aluminium alloys, steel, stainless steel or the like. The carrier portion 18 may be a current-carrying portion of the chip carrier 2. In the example shown, the chip carrier portion 18 of the leadframe 2 in particular may contain a busbar or correspond to such a busbar. The busbar 18 can be configured to carry an electrical current 8 which is intended to be captured or measured by the sensor chip 4. In this case, the busbar 18 can be configured such that the measurement current 8 generates, at the location of the at least one sensor element 6, a magnetic field that can be measured (e.g., is measurable) by the at least one sensor element 6. The busbar 18 can be configured or manufactured in one piece in particular. In the example shown, the busbar 18 may have two lateral indentations similar to FIG. 1, for example. A second portion 20 of the leadframe 2 may have one or more connecting conductors (or leads or lead fingers or pins). Only a single connecting conductor 20 can be seen in the lateral sectional view of FIG. 2A owing to the selected perspective. However, for example, any number of further connecting conductors can be arranged behind the connecting conductor 20 shown.

The sensor chip 4 may be attached to a mounting surface of the busbar 18 by way of an adhesive material (or an adhesive layer) 26, wherein, in the example shown, the rear side 14 of the sensor chip 4 may be facing the top side of the busbar 18. The adhesive material 26 may be, for example, an electrically insulating adhesive. The sensor chip 4 (or its at least one sensor element 6) may be configured to capture a physical variable. In this case, the sensor chip 4 and its sensor element 6 are not necessarily restricted to the capture of a certain or only a single physical variable. For example, the at least one sensor element 6 may be configured to capture at least one of a magnetic field, a voltage, a temperature, a pressure, a humidity, a movement, an acceleration, a distance, light, a gas, etc. In the example shown, the sensor element 6 may be configured to capture a magnetic field which is generated in particular by the measurement current 8 flowing through the busbar 18. Based on the captured magnetic field (or the captured magnetic flux density of the induced magnetic field), the intensity of the measurement current 8 can be determined.

In particular, the induced magnetic field can be measured without physical contact between the sensor chip 4 and the busbar 18 (e.g., galvanically isolated). In such a case, the sensor chip 4 (or more precisely at least one sensor element 6 of the sensor chip 4) may at least partially overlap the busbar 18, as viewed in the vertical direction. The physical signals captured by the sensor chip 4 or the sensor element 6 can be converted into electrical signals and forwarded via an electrical connection element 22 and a connecting conductor 20 to further components (not shown) for further processing or evaluation. Alternatively, processing or evaluation can also be carried out at least partially by the sensor chip 4. In the example shown, the electrical connection element 22 may correspond to or include a wire. Alternatively, or additionally, in further examples, the electrical connection element 22 may contain a clip, a band, or the like.

Generally, the sensor chip 4 and its sensor element(s) 6 are not limited to a specific sensor technology. For example, a sensor element 6 of the sensor chip 4 may be a Hall sensor element, a magneto-resistive sensor element, a vertical Hall sensor element or a fluxgate sensor element. An xMR magneto-resistive sensor element may be an AMR (anisotropic magneto-resistive) sensor element, a GMT (giant magneto-resistive) sensor element, or a TMR (tunnel magneto-resistive) sensor element. In one example, the sensor chip 4 may be a differential magnetic field sensor chip having two Hall sensor elements. The Hall sensor elements can be sensitive in a direction perpendicular to the chip front side 10. In further examples, the sensor chip 4 may contain a single magneto-resistive sensor element 6 (for example an AMR sensor element, a GMR sensor element, or a TMR sensor element). The magneto-resistive sensor element can be sensitive in a direction parallel to the chip front side 10. The shape of the busbar 18 and thus the course of the measurement current 8 can be selected depending on the sensitivity direction of the at least one sensor element 6 in order to achieve a sufficient signal strength at the location of the sensor element 6.

It should be noted that in the example shown, for the sake of simplicity, only a single sensor element 6 of the sensor chip 4 is shown. However, it is clear that, in further examples, the sensor chip 4 may have one or more further sensor elements which may be surrounded by the electrically insulating material 12 on the front side 10 of the sensor chip 4. The functionalities of the sensor elements can differ from each other. In a non-limiting and merely illustrative example, the sensor chip 4 may have a sensor element for measuring a magnetic field and a further sensor element for a temperature measurement.

The electrically insulating layer 16 arranged over the rear side 14 of the sensor chip 4 may be configured to provide vertical electrical insulation of the sensor chip 4 and/or of the at least one sensor element 6. More specifically, the electrically insulating layer 16 can provide galvanic isolation between the sensor chip 4 and the busbar 18 and/or galvanic isolation between the at least one sensor element 6 and the busbar 18. In the example shown, the electrically insulating layer 16 can cover the entire rear side 14 of the sensor chip 4 and thus ensure complete galvanic isolation between the sensor chip 4 and the busbar 18.

The electrically insulating layer 16 may contain or be produced from any suitable inorganic and/or organic material as long as it fulfils its intended functionality. In particular, the electrically insulating layer 16 may contain or be produced from at least one of the following materials: oxide, nitride, polyimide, epoxy, glass, ceramic, silicone, or the like. In the example shown, the electrically insulating layer 16 may have a substantially constant thickness in the vertical direction. In a non-limiting example, the thickness of the electrically insulating layer 16 in the vertical direction can be in a range of approximately 1 μm to approximately 10 μm. In this context, it should be noted that the thickness of the electrically insulating layer 16 may depend on the specific design and application of the sensor device 200, in particular on electrical potential differences that may occur between the sensor chip 4 and the busbar 18 during operation of the sensor device 200.

The electrically insulating layer 12 arranged on the front side 10 of the sensor chip 4 may be configured to provide lateral electrical insulation of the sensor chip 4 and/or of the at least one sensor element 6. In the example shown, the electrically insulating material 12 may have at least one trench 24 extending in a direction from the front side 10 to the rear side 14 through the sensor chip 4 and filled with an electrically insulating material. In the illustrated case, an example number of two trenches 24 is shown, which trenches can surround the at least one sensor element 6 (in particular completely), as can be seen in the plan view in FIG. 2B. In the example shown, the trenches 24 can have a substantially rectangular shape. In further examples, the closed shape of the trenches 24 can be chosen differently as desired, for example circular, elliptical, square, polygonal, etc.

The electrically insulating layer 12 or the electrically insulating trenches 24 may contain or be produced from any suitable inorganic and/or organic material as long as it/they fulfil(s) its/their intended functionality. In particular, the electrically insulating trenches 24 may contain or be produced from at least one of the following materials: oxide, nitride, polyimide, epoxy, glass, ceramic, silicone, or the like. In one example, all trenches 24 may be filled with the same electrically insulating material, while, in a further example, different trenches may be filled with different electrically insulating materials. The electrically insulating material 12 on the front side 10 and the electrically insulating layer 16 over the rear side 14 may be produced from the same material or from different materials.

In a non-limiting example, a depth of the trenches 24 in the vertical direction can be in a range of approximately 10 μm to approximately 200 μm (more specifically of approximately 10 μm to approximately 100 μm). In a non-limiting example, a width of the trenches 24 in the lateral direction can be in a range of approximately 1 μm to approximately 10 μm. In this context, it should be noted that the width of the trenches 24, the depth of the trenches 24 and/or the number of trenches 24 may depend on the specific design and application of the sensor device 200, in particular on electrical potential differences that may occur between the sensor chip 4 and the busbar 18 during operation of the sensor device 200.

In the example shown, the filled trenches 24 can make contact with the electrically insulating layer 16 on the rear side 14 of the sensor chip 4. In some examples, the filled trenches 24 and the electrically insulating layer 16 can thus form a trough-shaped or shell-shaped structure which can surround the at least one sensor element 6 of the sensor chip 4. The insulation properties already described can be provided in the lateral and vertical direction by virtue of such a geometric shape of the electrically insulating materials. The trough-shaped structure can be configured in particular to be continuous, contiguous and without openings.

In further examples, the electrically insulating material 12 on the front side 10 of the sensor chip 4 need not necessarily extend into the sensor chip 4, but can be arranged (in particular completely) over the front side 10 of the sensor chip 4 in order to provide lateral electrical insulation of the sensor chip 4 and/or of the at least one sensor element 6. In this case, the material 12 may form an edge structure in particular and be arranged at (or near) the edges of the chip front side 10. Such an arrangement of the electrically insulating material 12 makes it possible to reduce electric field strengths or electrical voltages on the front side 12 of the sensor chip 4 and in particular at the edges of the chip front side 10.

The sensor device 200 may have an encapsulation material 28 which is indicated by a dashed line in FIGS. 2A and 2B. In the example shown, the sensor chip 4 and the busbar 18 can be encapsulated at least partially in the encapsulation material 28. The encapsulation material 28 may form a housing (or package) for the encapsulated device components in order to protect them from external influences, such as mechanical effects, chemical impurities, moisture, exposure to light, etc. The sensor device 200 may also be referred to as a sensor package or semiconductor package. In particular, the busbar 18 can be a busbar inside the package. The busbar 18 may at least partially protrude from the encapsulation material 28 in order to provide an input and an output for the measurement current 8. In a similar manner, the connecting conductor 20 can protrude from the encapsulation material 28, such that the sensor chip 4 can be electrically accessible from outside the encapsulation material 28. The encapsulation material 28 may contain or be produced from at least one of an epoxy, an imide, a thermoplastic, a thermoset polymer, a polymer mixture, a laminate, or the like. Various techniques can be used for encapsulating the device components with the encapsulation material 28, for example at least one of compression moulding, injection moulding, powder moulding, liquid moulding, map moulding, lamination, or the like.

In some examples, the chip carrier portion or the busbar 18 may be electrically connected to a high-voltage terminal of the sensor device 200, while the sensor chip 4 may be electrically connected to a low-voltage terminal of the sensor device 200. During operation of the sensor device 200, the busbar 18 can thus be located in a high-voltage domain and the sensor chip 4 can be located in a low-voltage domain. This can cause large electrical potential differences between the busbar 18 and the sensor chip 4. By way of example, such voltage differences can assume values of more than 1000 volts, for example. The filled trenches 24 and the electrically insulating layer 16 make it possible to provide sufficient galvanic isolation between the busbar 18 and the sensor chip 4.

Due to the high voltage differences occurring between the sensor chip 4 and the busbar 18, locally increased electric field strengths may occur within the sensor device 200. In particular, the electric field strength may be increased in a region 30 (or a material triple point) in which the busbar 18, the sensor chip 4 (or the adhesive layer 26) and the encapsulation material 28 (if present) are adjacent to each other. Such a high electrical load can lead to accelerated ageing of the materials involved. In this context, delamination of the encapsulation material 28, electrical discharges and/or electrical “treeing” can occur, which can typically begin at corners and/or edges of the sensor chip 4 and/or the chip carrier 2. This may result in the formation of undesired breakdown paths between the sensor chip 4 and the busbar 18, which may result in failure of the sensor device 200 in the worst case. Using the filled trenches 24 and the electrically insulating layer 16 makes it possible to shift the regions of increased or maximum electric field strengths from problematic regions into the sensor chip 4, whereby the above-mentioned undesirable effects can be avoided or at least mitigated. The filled trenches 24 and/or the electrically insulating layer 16 can be used to tune or adjust the electric field (“E-field tuning”).

It should be noted that, depending on the application and design of the sensor device 200, one or more parameters can be adapted accordingly in order to provide the previously described galvanic isolation and/or shifting of regions of particularly high electric field strengths. These parameters may include in particular: the material of the electrically insulating layer 16, the thickness of the electrically insulating layer 16, the material of the filled trenches 24, the number of filled trenches 24, the depth of the filled trenches 24, the width of the filled trenches 24, the shape of the filled trenches 24, the position of the filled trenches 24. It is possible to dispense with cost-intensive and complex insulation, such as an additional dielectric plate (made of glass, for example) arranged between the busbar 18 and the sensor chip 4.

Furthermore, it should be noted that a particularly small distance between the sensor element 6 and the busbar 18 and thus a reduced overall height of the sensor device 200 can be achieved by virtue of the described aspects. Due to the small distance, a high magnetic field strength and thus the highest possible signal-to-noise ratio can be achieved at the location of the sensor element 6 during measurement. A performance of the sensor device 200 can thus also be achieved by virtue of the electrical insulation described herein.

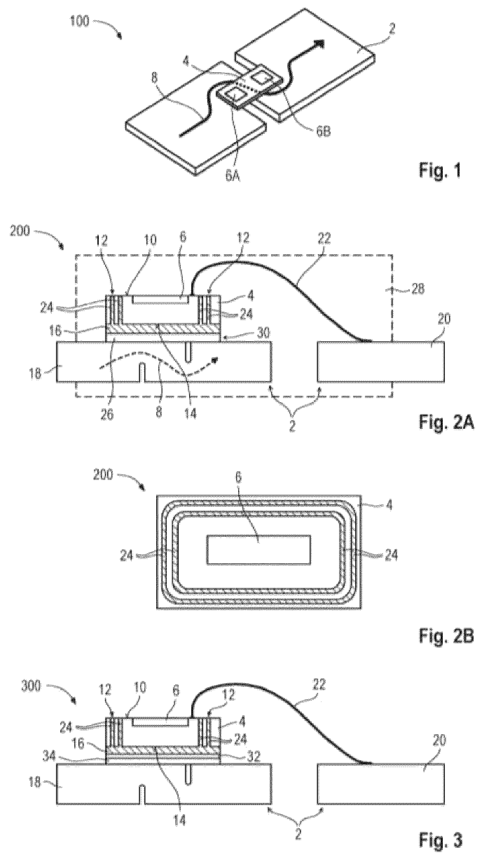

The sensor device 300 in FIG. 3 may have one or more features of sensor devices described above. In the example shown, the sensor device 300 may have a solderable metallization 32 arranged over the electrically insulating layer 16 and a solder material 34 arranged thereover. In an example, the metallization 32 may contain or be produced from copper or a copper alloy. The sensor device 300 need not necessarily be attached to the busbar 18 by an adhesive layer, as shown and described in the example in FIGS. 2A and 2B, but can instead be attached to the chip carrier portion 18 using a soldering operation. The adhesive layer described in connection with FIGS. 2A and 2B may have imperfections, such as foreign particles or air cavities. Increased electric field strengths can occur, in particular in air cavities, which can lead to gas discharges and associated degradation of the materials involved. This can be avoided by the alternative use of the solderable metallization 32 or chip attachment using a soldering operation. It is noted that attachment of the sensor chip 4 to the chip carrier 2 is not restricted to a specific method. In addition to the already described possibilities (adhesive bonding, soldering), the sensor chip 4 can also be effected, for example, by a sintering process or any other suitable technique.

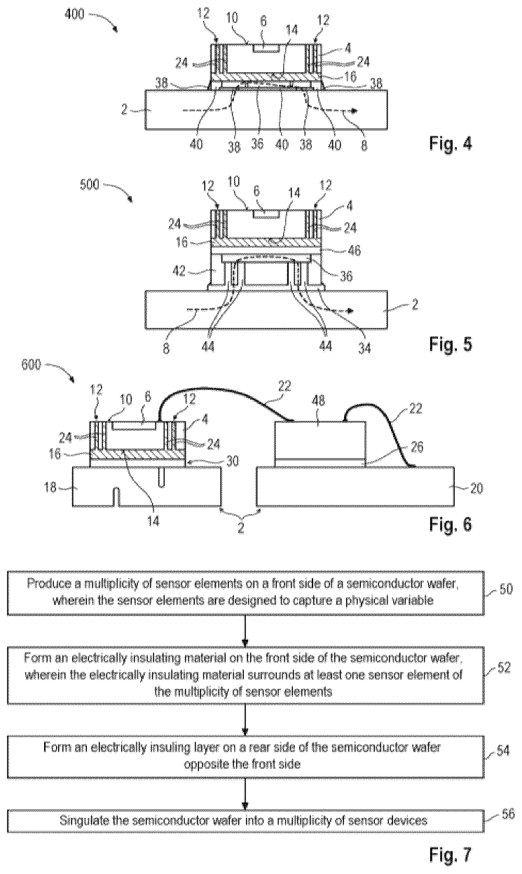

The sensor device 400 in FIG. 4 may have one or more features of sensor devices described above. In the example shown, possible connecting conductors of the sensor device 400 are not shown for the sake of simplicity. The sensor device 400 may have a structured metal layer 36 arranged over the electrically insulating layer 16. The metal layer 36 may be formed in such a way that an electrical current 8 flowing through the structured metal layer 36 generates, at the location of the at least one sensor element 6, a magnetic field that can be measured by the at least one sensor element 6. In the example shown, the structured metal layer 36 may have the same shape as or a similar shape to the busbar 18 in FIGS. 2A and 2B. As a result of two lateral indentations formed in the metal layer 36, the measurement current 8 can have a substantially s-shaped course, whereby a measurable magnetic field can be generated at the location of the sensor element 6. The chip carrier 2 must therefore no longer necessarily have a shape required for generating a suitable magnetic field, thus making it possible to dispense with sometimes elaborate structuring of the chip carrier 2. In other words, the functionality of the busbar of previous examples is provided at least partially by the structured metal layer 36 in the example in FIG. 4. The structured metal layer 36 can be produced in particular over the rear side 14 of the sensor chip 4 before the sensor chip 4 is mounted on the chip carrier 2.

The structured metal layer 36 and the chip carrier 2 can be electrically connected to each other. The measurement current 8 can thus flow through the chip carrier 2 and through the structured metal layer 36 and can generate a measurable magnetic field at the location of the at least one sensor element 6. In the example shown, the structured metal layer 36 can be arranged (in particular completely) within an outline of the sensor chip 4, as viewed from above. The structured metal layer 36 can be attached to the chip carrier 2, for example, using an electrically conductive adhesive 38. In this case, the adhesive 38 can provide an electrical connection between the chip carrier 2 and the structured metal layer 36. The intermediate spaces below the electrically insulating layer 16 may be filled with an electrically insulating material 40, for example an oxide.

The sensor device 500 in FIG. 5 may have one or more features of sensor devices described above. In the example shown, possible connecting conductors of the sensor device 500 are not shown for the sake of simplicity. The sensor device 500 may have a structured metal layer 36, as previously described in connection with the example in FIG. 4. Possible lateral indentations of the structured metal layer 36 are not shown. A carrier 42 having electrical vias 44 extending through the carrier 42 may be arranged over the underside of the structured metal layer 36. For example, the carrier 42 may be produced from a semiconductor material (e.g., silicon). In such a case, the vias 44 may include or correspond to TSVs (Through Silicon Vias), for example, which may extend in a vertical direction from the underside of the carrier 42 to its top side.

The carrier 42 and/or the structured metal layer 36 may be attached to the underside of the electrically insulating layer 16 using an adhesive material 46. For example, the adhesive material 46 may be a die-attach film. Furthermore, in the example shown, the carrier 42 may be attached on the top side of the chip carrier 2 using a solder material 34. The structured metal layer 36 and the chip carrier 2 can be electrically connected to each other via the electrical vias 44. The measurement current 8 can thus flow through the chip carrier 2, through the electrical vias 44 and through the structured metal layer 36 and can generate, at the location of the at least one sensor element 6, a magnetic field that can be measured by the at least one sensor element 6. In the example shown, the structured metal layer 36 may be at least partially integrated in the upper surface of the carrier 42. In this case, the top side of the carrier 42 and the top side of the structured metal layer 36 can be in particular flush, e.g., can essentially lie in a common plane.

The sensor device 600 in FIG. 6 may have one or more features of sensor devices described above. In the example shown, the sensor device 600 may have a logic semiconductor chip 48 which is configured to process measurement signals output by the sensor chip 4. For example, the logic semiconductor chip 48 may contain or correspond to an ASIC. Accordingly, the sensor chip 4 may be a discrete semiconductor chip, the basic function of which is to capture the magnetic field present at the location of the sensor element 6 and to output a measurement signal based thereon, while the measurement signal is processed (in particular completely) in the logic semiconductor chip 48. It is clear that in other examples measurement signals can be processed at least partially (or completely) in the sensor chip 4 itself. In the example shown, the logic semiconductor chip 48 may be attached to a connecting conductor 20 using an adhesive material 26. The sensor chip 4 and the logic semiconductor chip 48 can be electrically coupled to each other via an electrical connection element 22. Furthermore, the logic semiconductor chip 48 can be electrically connected to the connecting conductor 20 via a further electrical connection element 22.

FIG. 7 shows a method for producing a sensor device according to the disclosure. The method is illustrated in a general way in order to specify aspects of the disclosure qualitatively. The method can be used, for example, to produce sensor devices described above and can therefore be read in conjunction with preceding figures. The method may be extended by aspects which are described in conjunction with other examples discussed herein. Example extensions of the method are clear from the previous examples.

In a step 50, a multiplicity of sensor elements (e.g., a plurality of sensor elements) can be produced on a front side of a semiconductor wafer, wherein the sensor elements are configured to capture a physical variable. In a step 52, an electrically insulating material can be formed on the front side of the semiconductor wafer, wherein the electrically insulating material surrounds at least one sensor element of the multiplicity of sensor elements. In a step 54, an electrically insulating layer can be formed on a rear side of the semiconductor wafer opposite the front side. In a step 56, the semiconductor wafer may be singulated into a multiplicity of sensor devices.

In one example, the electrically insulating material can be formed on the front side by initially forming a multiplicity of trenches extending through the semiconductor wafer in a direction from the front side to the rear side of the semiconductor wafer. Each of the trenches can surround at least one sensor element of the multiplicity of sensor elements. The trenches can then be filled with an electrically insulating material which can make contact with the electrically insulating layer on the chip rear side. A sensor device according to the disclosure with such filled trenches is shown, for example, in FIGS. 2A and 2B.

In a further example, a solderable metallization can be formed over the rear side of the semiconductor wafer after the formation of the electrically insulating layer. After singulating the semiconductor wafer, a sensor device obtained in this way can be attached to a chip carrier using a soldering operation, as shown and described, for example, in connection with FIG. 3.

In a further example, a structured metal layer can be formed over the rear side of the semiconductor wafer after the formation of the electrically insulating layer. In this case, the structured metal layer may be formed in such a way that an electrical current flowing through the structured metal layer generates, at the locations of the sensor elements, a magnetic field that can be measured by the sensor elements. After singulating the semiconductor wafer, a sensor device can be obtained, as shown, for example, in FIG. 4.

In a further example, a carrier wafer can be attached over the rear side of the semiconductor wafer after the formation of the electrically insulating layer, wherein the carrier wafer may have a multiplicity of electrical vias extending through the carrier wafer. After singulating the semiconductor wafer, a sensor device may be produced, as shown, for example, in FIG. 5.

### ASPECTS

Sensor devices according to the disclosure and associated production methods are described below based on aspects.

Aspect 1 is a sensor device, comprising: a sensor chip having at least one sensor element which is arranged on a front side of the sensor chip and is configured to capture a physical variable; an electrically insulating material which is arranged on the front side of the sensor chip and surrounds the at least one sensor element; and an electrically insulating layer arranged over a rear side of the sensor chip opposite the front side.

Aspect 2 is a sensor device according to Aspect 1, wherein the at least one sensor element is configured to capture a magnetic field.

Aspect 3 is a sensor device according to Aspect 1 or 2, wherein the electrically insulating material comprises at least one trench which extends through the sensor chip in a direction from the front side to the rear side and is filled with an electrically insulating material, wherein the at least one filled trench surrounds the at least one sensor element and makes contact with the electrically insulating layer.

Aspect 4 is a sensor device according to one of the preceding aspects, further comprising: an electrically conductive chip carrier, wherein the sensor chip is arranged above a portion of the chip carrier, and wherein the electrically insulating layer provides galvanic isolation between the chip carrier portion and the at least one sensor element.

Aspect 5 is a sensor device according to Aspect 4, wherein the chip carrier portion comprises a busbar which is configured such that an electrical current flowing through the busbar generates, at the location of the at least one sensor element, a magnetic field that can be measured by the at least one sensor element.

Aspect 6 is a sensor device according to one of Aspects 3 to 5, wherein the at least one filled trench and the electrically insulating layer form a trough-shaped structure which surrounds the at least one sensor element.

Aspect 7 is a sensor device according to one of the preceding aspects, wherein the electrically insulating material and/or the electrically insulating layer comprise(s) at least one of oxide, nitride, polyimide, epoxy.

Aspect 8 is a sensor device according to one of the preceding aspects, further comprising: a solderable metallization arranged over the electrically insulating layer.

Aspect 9 is a sensor device according to one of the preceding aspects, further comprising: a structured metal layer arranged over the electrically insulating layer, wherein the structured metal layer is formed in such a way that an electrical current flowing through the structured metal layer generates, at the location of the at least one sensor element, a magnetic field that can be measured by the at least one sensor element.

Aspect 10 is a sensor device according to Aspect 9, wherein the structured metal layer is arranged within an outline of the sensor chip.

Aspect 11 is a sensor device according to Aspect 4 and either of Aspects 9 and 10, wherein: the structured metal layer and the chip carrier portion are electrically connected to each other, and an electrical current flowing through the structured metal layer and through the chip carrier portion generates, at the location of the at least one sensor element, a magnetic field that can be measured by the at least one sensor element.

Aspect 12 is a sensor device according to one of Aspects 9 to 11, further comprising: a carrier arranged over the structured metal layer and having electrical vias extending through the carrier.

Aspect 13 is a sensor device according to Aspects 4 and 12, wherein: the structured metal layer and the chip carrier portion are electrically connected to each other via the electrical vias, and an electrical current flowing through the structured metal layer, through the electrical vias, and through the chip carrier portion generates, at the location of the at least one sensor element, a magnetic field that can be measured by the at least one sensor element.

Aspect 14 is a sensor device according to Aspect 12 or 13, wherein the structured metal layer is at least partially integrated in a surface of the carrier.

Aspect 15 is a sensor device according to one of Aspects 4 to 14, further comprising: an encapsulation material, wherein the sensor chip and the chip carrier portion are encapsulated in the encapsulation material.

Aspect 16 is a sensor device according to one of the preceding aspects, further comprising: at least one further sensor element, wherein the electrically insulating material surrounds the at least one further sensor element, wherein a functionality of the at least one sensor element differs from a functionality of the at least one further sensor element.

Aspect 17 is a sensor device according to one of the preceding aspects, further comprising: a logic semiconductor chip, wherein the sensor chip is a discrete semiconductor chip and is connected to the logic semiconductor chip, and wherein the logic semiconductor chip is configured to process measurement signals output by the sensor chip.

Aspect 18 is a method for producing a sensor device, wherein the method comprises: producing a multiplicity of sensor elements on a front side of a semiconductor wafer, wherein the sensor elements are configured to capture a physical variable; forming an electrically insulating material on the front side of the semiconductor wafer, wherein the electrically insulating material surrounds at least one sensor element of the multiplicity of sensor elements; forming an electrically insulating layer on a rear side of the semiconductor wafer opposite the front side; singulating the semiconductor wafer into a multiplicity of sensor devices.

Aspect 19 is a method according to Aspect 18, wherein the sensor elements are configured to capture a magnetic field.

Aspect 20 is a method according to Aspect 18 or 19, wherein the formation of the electrically insulating material on the front side of the semiconductor wafer comprises: forming a multiplicity of trenches extending through the semiconductor wafer in a direction from the front side to the rear side of the semiconductor wafer, wherein each of the trenches surrounds at least one sensor element of the multiplicity of sensor elements, and filling the trenches with an electrically insulating material which makes contact with the electrically insulating layer. The trenches may be filled from the front side to make contact with the electrically insulating material arranged at the rear side.

Aspect 21 is a method according to one of Aspects 18 to 20, further comprising: forming a solderable metallization over the rear side of the semiconductor wafer after the formation of the electrically insulating layer.

Aspect 22 is a method according to one of Aspects 18 to 21, further comprising: forming a structured metal layer over the rear side of the semiconductor wafer after the formation of the electrically insulating layer, wherein the structured metal layer is formed in such a way that an electrical current flowing through the structured metal layer generates, at the locations of the sensor elements, a magnetic field that can be measured by the sensor elements.

Aspect 23 is a method according to one of Aspects 18 to 22, further comprising: attaching a carrier wafer over the rear side of the semiconductor wafer after the formation of the electrically insulating layer, wherein the carrier wafer has a multiplicity of electrical vias extending through the carrier wafer.

It should be pointed out that the description and the drawings only illustrate the principles of the proposed methods and devices. A person skilled in the art will be capable of implementing different arrangements which, although not expressly described or shown here, embody the principles of the implementation and are contained within the scope thereof. In addition, all aspects and implementations outlined in the present document are intended fundamentally and expressly for explanatory purposes only, in order to help the reader understand the principles of the proposed methods and devices. In addition, all statements in this document that describe principles, aspects and implementations of the implementation and specific aspects thereof are also intended to encompass their equivalents.

1. A sensor device, comprising:
a sensor chip having at least one sensor element which is arranged on a front side of the sensor chip and is configured to capture a physical variable;
an electrically insulating material which is arranged on the front side of the sensor chip and surrounds the at least one sensor element; and
an electrically insulating layer arranged over a rear side of the sensor chip, the rear side being arranged opposite the front side.

2. The sensor device according to claim 1, wherein the at least one sensor element is configured to capture a magnetic field.

3. The sensor device according to claim 1, wherein the electrically insulating material comprises at least one filled trench which extends through the sensor chip in a direction from the front side to the rear side and is filled with the electrically insulating material, and
wherein the at least one filled trench surrounds the at least one sensor element and makes contact with the electrically insulating layer.

4. The sensor device according to claim 1, further comprising:
an electrically conductive chip carrier,
wherein the sensor chip is arranged above a chip carrier portion of the electrically conductive chip carrier, and
wherein the electrically insulating layer provides galvanic isolation between the chip carrier portion and the at least one sensor element.

5. The sensor device according to claim 4, wherein the chip carrier portion comprises a busbar which is configured such that an electrical current flowing through the busbar generates, at a location of the at least one sensor element, a magnetic field that is measurable by the at least one sensor element.

6. The sensor device according to claim 3, wherein the at least one filled trench and the electrically insulating layer form a trough-shaped structure which surrounds the at least one sensor element.

7. The sensor device according to claim 1, wherein the electrically insulating material and/or the electrically insulating layer comprise(s) at least one of oxide, nitride, polyimide, epoxy.

8. The sensor device according to claim 1, further comprising:
a solderable metallization arranged over the electrically insulating layer.

9. The sensor device according to claim 1, further comprising:
a structured metal layer arranged over the electrically insulating layer, wherein the structured metal layer is formed in such a way that an electrical current flowing through the structured metal layer generates, at a location of the at least one sensor element, a magnetic field that is measurable by the at least one sensor element.

10. The sensor device according to claim 9, wherein the structured metal layer is arranged within an outline of the sensor chip.

11. The sensor device according to claim 9, further comprising:
an electrically conductive chip carrier,
wherein the sensor chip is arranged above a chip carrier portion of the electrically conductive chip carrier,
wherein the electrically insulating layer provides galvanic isolation between the chip carrier portion and the at least one sensor element,
wherein the structured metal layer and the chip carrier portion are electrically connected to each other, and
wherein an electrical current flowing through the structured metal layer and through the chip carrier portion generates, at a location of the at least one sensor element, a magnetic field that is measurable by the at least one sensor element.

12. The sensor device according to claim 9, further comprising:
a carrier arranged over the structured metal layer and having electrical vias extending through the carrier.

13. The sensor device according to claim 12, further comprising:
an electrically conductive chip carrier,
wherein the sensor chip is arranged above a chip carrier portion of the electrically conductive chip carrier,
wherein the electrically insulating layer provides galvanic isolation between the chip carrier portion and the at least one sensor element,
wherein the structured metal layer and the chip carrier portion are electrically connected to each other via the electrical vias, and
wherein an electrical current flowing through the structured metal layer, through the electrical vias and through the chip carrier portion generates, at a location of the at least one sensor element, a magnetic field that is measurable by the at least one sensor element.

14. The sensor device according to claim 12, wherein the structured metal layer is at least partially integrated in a surface of the carrier.

15. The sensor device according to claim 4, further comprising:
an encapsulation material,
wherein the sensor chip and the chip carrier portion are encapsulated in the encapsulation material.

16. The sensor device according to claim 1, further comprising:
at least one further sensor element,
wherein the electrically insulating material surrounds the at least one further sensor element, and
wherein a functionality of the at least one sensor element differs from a functionality of the at least one further sensor element.

17. The sensor device according to claim 1 further comprising:
a logic semiconductor chip,
wherein the sensor chip is a discrete semiconductor chip and is connected to the logic semiconductor chip, and
wherein the logic semiconductor chip is configured to process measurement signals output by the sensor chip.

18. A method for producing a sensor device, wherein the method comprises:
producing a multiplicity of sensor elements on a front side of a semiconductor wafer, wherein the sensor elements are configured to capture a physical variable;
forming an electrically insulating material on the front side of the semiconductor wafer, wherein the electrically insulating material surrounds at least one sensor element of the multiplicity of sensor elements;
forming an electrically insulating layer on a rear side of the semiconductor wafer, the rear side being arranged opposite the front side; and
singulating the semiconductor wafer into a multiplicity of sensor devices.

19. The method according to claim 18, wherein the multiplicity of sensor elements are configured to capture a magnetic field.

20. The method according to claim 18, wherein forming the electrically insulating material on the front side of the semiconductor wafer comprises:
forming a multiplicity of trenches extending through the semiconductor wafer in a direction from the front side to the rear side of the semiconductor wafer, wherein each trench of the multiplicity of trenches surrounds the at least one sensor element of the multiplicity of sensor elements; and
filling the multiplicity of trenches with the electrically insulating material which makes contact with the electrically insulating layer.

21. The method according to claim 18, further comprising:
after forming the electrically insulating material, forming a solderable metallization over the rear side of the semiconductor wafer.

22. The method according to claim 18, further comprising:
after forming the electrically insulating material, forming a structured metal layer over the rear side of the semiconductor wafer,
wherein the structured metal layer is formed in such a way that an electrical current flowing through the structured metal layer generates, at locations of the multiplicity of sensor elements, a magnetic field that is measurable by the multiplicity of sensor elements.

23. The method according to claim 18, further comprising:
after forming the electrically insulating material, attaching a carrier wafer over the rear side of the semiconductor wafer,
wherein the carrier wafer has a multiplicity of electrical vias extending through the carrier wafer.
